(19) United States
(12) Patent Application Publication
(10) Pub. No.: US 2023/0380099 A1
(43) Pub. Date: Nov. 23, 2023

(54) SYSTEMS WITH AT LEAST ONE MULTI-FINGER PLANAR CIRCUIT BOARD FOR INTERCONNECTING MULTIPLE CHASSIS

(71) Applicant: Microsoft Technology Licensing, LLC, Redmond, WA (US)

(72) Inventor: Wade John DOLL, Enumclaw, WA (US)

(21) Appl. No.: 17/746,600

(22) Filed: May 17, 2022

(51) Int. Cl. H05K 7/14; H05K 7/20

(52) U.S. Cl. CPC H05K 7/1492; H05K 7/20718

(57) ABSTRACT

Systems with multi-finger planar circuit boards for interconnecting multiple chassis are described. A system includes: (1) a first chassis arranged in a first plane, (2) a second chassis arranged in a second plane, and (3) a third chassis including a shared resource, arranged in a third plane between the first plane and the second plane. The system includes a planar circuit board (PCB) arranged in a fourth plane, orthogonal to the third plane. A first finger of the PCB, configured to provide a first physical path for an exchange of signals between the first chassis and shared resource, extends through a first gap between the first chassis and the third chassis. A second finger of the PCB, configured to provide a second physical path for an exchange of signals between the second chassis and third chassis, extends through a second gap between the second chassis and the shared resource.

### BACKGROUND

Multiple tenants may share systems, including computing systems and communications systems. Computing systems may include the public cloud, the private cloud, or a hybrid cloud having both public and private portions. The public cloud includes a global network of servers that perform a variety of functions, including storing and managing data, running applications, and delivering content or services, such as streaming videos, provisioning electronic mail, providing office productivity software, or handling social media. The servers and other components may be located in data centers across the world. While the public cloud offers services to the public over the Internet, businesses may use private clouds or hybrid clouds. Both private and hybrid clouds also include a network of servers housed in data centers.

Multiple tenants may use compute, storage, and networking resources associated with the servers in the cloud. The compute, storage, and networking resources may be provisioned in a data center using racks or trays of servers. Interconnecting the disparate servers via cables can interfere with airflow being used to cool the servers. This is because the cables may block the air being used to cool the servers. In addition, access to the servers for servicing may also be impeded by the considerable number of cables required for interconnecting the servers. Similarly, back planes used for interconnecting the servers may also interfere with the airflow being used to cool the servers. Accordingly, there is a need for better systems for interconnecting servers.

### SUMMARY

In one example, the present disclosure relates to a system comprising a first chassis including a first set of electronic devices corresponding to a first server, where the first chassis is arranged in a first plane. The system may further comprise a second chassis including a second set of electronic devices corresponding to a second server, where the second chassis is arranged in a second plane on top of the first plane and parallel to the first plane. The system may further comprise a third chassis including a third set of electronic devices configured to provide a shared resource shareable by the first set of electronic devices and the second set of electronic devices, where the third chassis is arranged in a third plane between the first plane and the second plane.

The system may further comprise a planar circuit board including a plurality of fingers extending from a portion of the planar circuit board. The planar circuit board may be arranged in a fourth plane, orthogonal to each of the first plane, the second plane, and the third plane such that a first finger of the plurality of fingers extends through a first gap between the first chassis and the third chassis, where the first finger is configured to provide a first physical path for an exchange of signals between the first set of electronic devices and the third set of electronic devices, where a second finger of the plurality of fingers extends through a second gap between the second chassis and the third chassis, and where the second finger is configured to provide a second physical path for an exchange of signals between the second set of electronic devices and the third set of electronic devices.

In addition, the present disclosure relates to a system comprising a first chassis including a first set of electronic devices corresponding to a first server, where the first chassis is arranged in a first plane. The system may further comprise a second chassis including a second set of electronic devices corresponding to a second server, where the second chassis is arranged in a second plane on top of the first plane and parallel to the first plane. The system may further comprise a third chassis including a third set of electronic devices configured to provide a shared resource shareable by the first set of electronic devices and the second set of electronic devices, where the third chassis is arranged in a third plane between the first plane and the second plane.

The system may further comprise a planar circuit board including a plurality of fingers extending from a portion of the planar circuit board. The planar circuit board may be arranged in a fourth plane, orthogonal to each of the first plane, the second plane, and the third plane such that a first finger of the plurality of fingers extends through a first gap between the first chassis and the third chassis, where the first finger is configured to provide a first physical path for an exchange of signals between the first set of electronic devices and the third set of electronic devices, where a second finger of the plurality of fingers extends through a second gap between the second chassis and the third chassis, and where the second finger is configured to provide a second physical path for an exchange of signals between the second set of electronic devices and the third set of electronic devices, where the first finger comprises a first rigid portion and a first flexible portion, and where the second finger comprises a second rigid portion and a second flexible portion.

In addition, the present disclosure relates to a system comprising a first chassis including a first set of electronic devices corresponding to a first server, where the first chassis is arranged in a first plane. The system may further comprise a second chassis including a second set of electronic devices corresponding to a second server, where the second chassis is arranged in a second plane on top of the first plane and parallel to the first plane. The system may further comprise a third chassis including a third set of electronic devices configured to provide a shared resource shareable by the first set of electronic devices and the second set of electronic devices, where the third chassis is arranged in a third plane between the first plane and the second plane.

The system may further comprise a planar circuit board including a plurality of fingers extending from a portion of the planar circuit board. The planar circuit board may be arranged in a fourth plane, orthogonal to each of the first plane, the second plane, and the third plane such that a first finger of the plurality of fingers extends through a first gap between the first chassis and the third chassis, where the first finger is configured to provide a first physical path for an exchange of signals between the first set of electronic devices and the third set of electronic devices, where a second finger of the plurality of fingers extends through a second gap between the second chassis and the third chassis, where the second finger is configured to provide a second physical path for an exchange of signals between the second set of electronic devices and the third set of electronic devices, and where neither the first physical path nor the second physical path comprises any signal conditioning components configured to retime or amplify any signals.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 is a block diagram of a system including multi-finger planar circuit boards for interconnecting multiple chassis in accordance with one example;

FIG. 2 is a block diagram of an example memory chassis for use with the system of FIG. 1;

FIG. 3 shows an example multi-finger planar circuit board for use with the system of FIG. 1;

FIG. 4 shows a modified finger for use with the multi-finger planar circuit board of FIG. 3;

FIG. 5 shows a block diagram of the system of FIG. 1 with a cover configured to both reduce electromagnetic interference and deter tampering with the planar circuit board;

FIG. 6 shows a block diagram of an example computing system implemented using the system of FIG. 1; and

FIG. 7 shows a block diagram of a data center for housing a system including multi-finger planar circuit boards for interconnecting multiple chassis in accordance with one example.

### DETAILED DESCRIPTION

Examples described in this disclosure relate to systems with at least one multi-finger planar circuit board for interconnecting multiple chassis. In certain examples, such systems are configurable as computing systems or multi-tenant computing systems. The multi-tenant computing system may be a public cloud, a private cloud, or a hybrid cloud. The public cloud includes a global network of servers that perform a variety of functions, including storing and managing data, running applications, and delivering content or services, such as streaming videos, electronic mail, office productivity software, or social media. The servers and other components may be located in data centers across the world. While the public cloud offers services to the public over the Internet, businesses may use private clouds or hybrid clouds. Both private and hybrid clouds also include a network of servers housed in data centers. Compute entities may be executed using compute and memory resources of the data center. As used herein, the term “compute entity” encompasses, but is not limited to, any executable code (in the form of hardware, firmware, software, or in any combination of the foregoing) that implements a functionality, a virtual machine, an application, a service, a micro-service, a container, or a unikernel for serverless computing. Alternatively, compute entities may be executing on hardware associated with an edge-compute device, on-premises servers, or other types of systems, including communications systems, such as base stations (e.g., 5G or 6G base stations).

As noted earlier, interconnecting the disparate servers via cables can interfere with the airflow being used to cool the servers or other components housed in chassis. This is because the cables may block the air being used to cool the servers. In addition, access to the servers for servicing may also be impeded by the cables used for interconnecting the servers. Similarly, the back planes used for interconnecting the servers may also interfere with the airflow being used to cool the servers. In addition, the use of back planes may increase the distance that the input/output signals need to travel, resulting in signal integrity issues.

Certain examples of the present disclosure relate to a means for transferring input/output signals from a chassis having a server to a chassis having another server. Additional examples relate to means for transferring input/output signals from a chassis having a server to another chassis having a shared resource (e.g., a shared memory resource or a shared networking resource). One or more multi-finger planar circuit boards may be used to transfer such input/output signals. The multi-finger planar circuit boards may be arranged in a plane that is orthogonal to the plane in which the chassis including the server and the shared resource are arranged. In addition, the multi-finger planar circuit boards may be arranged in a plane that is parallel to the direction of airflow being used to cool the servers and the shared resource. The use of the planar circuit boards that are oriented orthogonal to the servers but planar to the airflow minimizes impediments to the airflow.

In addition, by using planar circuit boards that contain primarily passive electronic devices and wires, the circuit boards can have a low profile. Moreover, such use of planar circuit boards can leverage existing server designs without significantly modifying the server designs. This is because, as an example, the planar circuit boards may replace a subset of the traditional solid state drive bays. This may allow the use of such planar circuit boards without modifying the server designs.

In addition, unlike back plane solutions in which the signals from processors in one chassis to memory in another chassis need to travel long distances, the planar circuit boards do not require the signals to travel from the processors to the back of the chassis and then to the memory in the front again. This, in turn, means that the signal losses are lower with the use of the planar circuit boards as described herein. As a result, the signal paths may not need any retiming or re-driving of the signals traveling across the physical links used for interconnecting the chassis. This, in turn, means that the cost of such re-timer or re-driver components may be eliminated. Moreover, the power consumed by such components may also be saved.

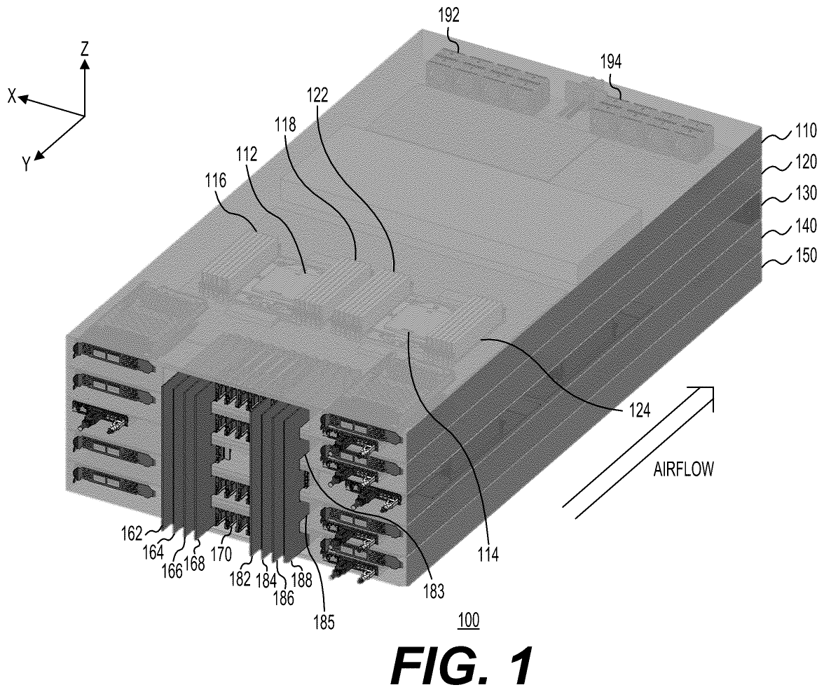

FIG. 1 is a block diagram of a system 100 including multiple chassis and multi-finger planar circuit boards for interconnecting the multiple chassis in accordance with one example. In this example, system 100 includes five chassis: chassis 110, chassis 120, chassis 130, chassis 140, and chassis 150. Each chassis may include electronic devices that may be used to provide compute, storage, or networking resources offered by system 100. In this example, each of chassis 110, chassis 120, chassis 140, and chassis 150 may be configured as a server. Chassis 130 may be configured to provide a set of shared resources (e.g., memory resources or networking resources) that could be shared by the servers in the other chassis.

With continued reference to FIG. 1, chassis 110 may include electronic devices, such as central processing units (CPUs), graphics processing units (GPUs), memory modules, Field-Programmable Gate Arrays (FPGAs), Application-Specific Integrated Circuits (ASICs), Application-Specific Standard Products (ASSPs), System-on-a-Chip systems (SOCs), Complex Programmable Logic Devices (CPLDs), and the like. In this example, the electronic devices may include CPUs 112 and 114, and memory modules 116, 118, 122, and 124. Examples of such memory modules include, but are not limited to, dual-in-line memory modules (DIMMs) or single-in-line memory modules (SIMMs). Memory included in these modules may be dynamic random access memory (DRAM), flash memory, static random access memory (SRAM), phase change memory, magnetic random access memory, or any other type of memory technology. CPUs 112 and 114 may access the memory via memory controllers. The memory controllers included in each CPU may be a double dynamic rate (DDR) DRAM controller in case the memory modules include DDR DRAM. In this example, each of chassis 110, chassis 120, chassis 140, and chassis 150 may be configured as a server and include similar electronic devices (e.g., CPUs, memory modules, and other electronic devices described with respect to chassis 110). Chassis 130 may be configured to provide a set of shared resources (e.g., memory resources or networking resources) that could be shared by the servers in the other chassis. Each chassis configured as a server may further include solid-state memory 170 (e.g., flash memory).

Still referring to FIG. 1, the electronic devices associated with the chassis may generate output signals and receive input signals during the operation of the various servers and the shared memory. As an example, CPUs associated with the servers may access memory located as part of chassis 130 that is shared among the servers in chassis 110, 120, 140, and 150, respectively. Such signals will require to be routed from a chassis having a server (e.g., chassis 110) to a chassis having the shared resource (e.g., shared memory in chassis 130). In this example, such input/output signals may be exchanged via multi-finger circuit boards 162, 164, 166, and 168 that are shown on the left side of the chassis and via multi-finger circuit boards 182, 184, 186, and 188 that are shown on the right side of the chassis. As shown in FIG. 1, the chassis configured as a server (e.g., chassis 110, 120, 140, and 150) are arranged in planes (e.g., a plane in the X-direction) that are parallel to each other. The chassis having the shared resource (e.g., chassis 130) is arranged in a plane that is between the planes corresponding to the chassis configured as the servers.

The multi-finger circuit boards (e.g., multi-finger circuit boards 162, 164, 166, 168, 182, 184, 186, and 188) are arranged in a plane (e.g., a plane in the Z direction) that is orthogonal to the planes corresponding to both the chassis configured as servers (e.g., chassis 110, 120, 140, and 150) and the chassis configured as having the shared resource (e.g., chassis 130). Fingers (e.g., fingers 183 and 185) extend between the chassis to provide physical paths for input/output signals being exchanged between the electronic devices associated with the chassis configured as a server and the chassis configured as the shared resource. As an example, finger 183 extends through a gap between chassis 120 and chassis 130. With appropriate connectors that connect finger 183 to connectors associated with chassis 120 and chassis 130, a physical path for exchange of signals among the electronic devices associated with respective chassis is formed. As another example, finger 185 extends through a gap between chassis 130 and chassis 140. With appropriate connectors that connect finger 185 to connectors associated with chassis 130 and chassis 140, a physical path for exchange of signals among the electronic devices associated with respective chassis is formed. Other fingers associated with the multi-finger circuit boards also allow for the exchange of signals among the chassis configured as servers.

With continued reference to FIG. 1, a cooling system, including fans such as fan 192 and fan 194, may be used to circulate air through each chassis. In this example, fans 192 and 194 create an airflow along the Y-axis in the direction shown in FIG. 1. As shown in FIG. 1, multi-finger circuit boards 162, 164, 166, 168, 182, 184, 186, and 188 are arranged in a plane (e.g., a plane in the Z direction) that is planar with respect to the principal direction (e.g., X-direction in FIG. 1) of the airflow. Thus, as the air flows from the front of the chassis towards the back (or in the opposite direction), the principal direction of the airflow is planar with respect to the plane in which the multi-finger circuit boards are situated. As a result, these multi-finger circuit boards 162, 164, 166, 168, 182, 184, 186, and 188 do not impede the air being used to cool the components associated with the chassis.

In one example, system 100 of FIG. 1 may be part of a data center. As used in this disclosure, the term data center may include, but is not limited to, some or all of the data centers owned by a cloud service provider, some or all of the data centers owned and operated by a cloud service provider, some or all of the data centers owned by a cloud service provider that are operated by a customer of the service provider, any other combination of the data centers, a single data center, or even some clusters in a particular data center. In one example, each cluster may include several identical servers. Thus, a cluster may include servers having a certain number of CPU cores and a certain amount of memory. Other types of hardware such as edge-compute devices, on-premises servers, or other types of systems, including communications systems, such as base stations (e.g., 5G or 6G base stations) may also be used. Although FIG. 1 shows system 100 as having a certain number of components, including server and memory components, arranged in a certain manner, system 100 may include additional or fewer components, arranged differently. As an example, although each chassis configured as a server (e.g., chassis 110) in FIG. 1 is shown as having two CPUs, each server may include additional CPUs, and other devices, such as graphics processor units (GPUs), field programmable gate arrays (FPGAs), application specific integrated circuits (ASICs), or other devices.

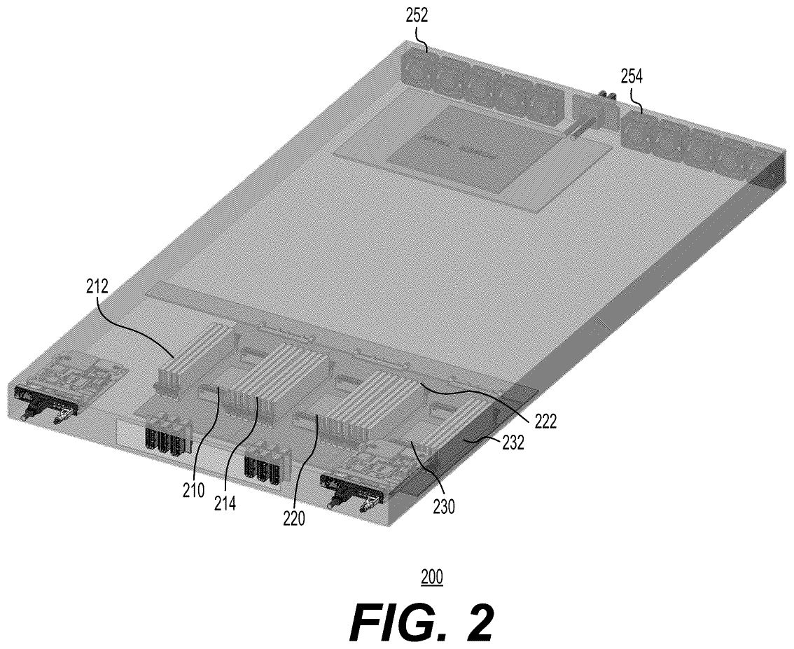

FIG. 2 is a block diagram of an example memory chassis 200 for use with system 100 of FIG. 1. Memory chassis 200 may include memory controllers 210, 220, and 230, which may be coupled to memory modules (e.g., memory modules 212, 214, 222, and 232). The memory controllers included in memory chassis 200 may be double dynamic rate (DDR) DRAM controllers in case the memory modules include DDR DRAM. Memory chassis 200 may include pooled memory (or non-pooled memory), which may include several memory modules (e.g., memory modules 212, 214, 222, and 232). Examples of such memory modules include, but are not limited to, dual-in-line memory modules (DIMMs) or single-in-line memory modules (SIMMs). Memory included in these modules may be dynamic random access memory (DRAM), flash memory, static random access memory (SRAM), phase change memory, magnetic random access memory, or any other type of memory technology that can allow the memory to act as far memory. A cooling system, including fans such as fan 252 and fan 254, may be used to circulate air through memory chassis 200.

Consistent with the examples of the present disclosure, a host OS may have access to a combination of near memory (e.g., the local DRAM) and an allocated portion of a far memory (e.g., pooled memory or non-pooled memory that is at least one level removed from the near memory). The far memory may relate to memory that includes any physical memory that is shared by multiple servers. As an example, the near memory may correspond to double data rate (DDR) dynamic random access memory (DRAM) that operates at a higher data rate (e.g., DDR2 DRAM, DDR3 DRAM, DDR4 DRAM, or DDR5 DRAM) and the far memory may correspond to DRAM that operates at a lower data rate (e.g., DRAM or DDR DRAM). Other cost differences may be a function of the reliability or other differences in quality associated with the near memory versus the far memory. As used herein the term “near memory” and “far memory” are to be viewed in relative terms. Thus, near memory includes any memory that is used for storing any data or instructions that is evicted from the system level cache(s) associated with a CPU and the far memory includes any memory that is used for storing any data or instruction swapped out from the near memory. Another distinction between the near memory and the far memory relates to the relative number of physical links between the CPU and the memory. As an example, assuming the near memory is coupled via a near memory controller, thus being at least one physical link away from the CPU, the far memory is coupled to a far memory controller, which is at least one more physical link away from the CPU.

Any of the host OS being executed by any of severs associated with the chassis configured as a server (e.g., chassis 110, 120, 140, and 150) may access at least a portion of the physical memory included as part of the far memory of chassis 130. A portion of memory from this far memory may be allocated to the server when the server powers on or as part of allocation/deallocation operations. The assigned portion may include one or more “slices” of memory, where a slice refers to any smallest granularity of portions of memory managed by the far memory controller (e.g., a memory page or any other block of memory aligned to a slice size). A slice of memory is allocated at most to only one host at a time. Any suitable slice size may be used, including 1 GB slices, 2 GB slices, 8 GB slices, or any other suitable slice sizes. The far memory controller may assign or revoke assignment of slices to servers based on an assignment/revocation policy associated with the far memory. Data/instructions associated with a host OS may be swapped in and out of the near memory from/to the far memory.

A far memory system may be provisioned using chassis 200 including a switch for coupling the far memory to servers (e.g., compute servers housed in chassis 110, 120, 140, and 150 of FIG. 1). Each of the far memory controllers may be implemented as a Compute Express Link (CXL) specification compliant memory controller. In this example, each of the memory modules associated with the far memory may be configured as Type 3 CXL devices. A CXL specification compliant fabric manager may allocate a slice of memory from within the far memory (provisioned via chassis 200) to a specific server in a time-division multiplexed fashion. In other words, at a time a particular slice of memory could only be allocated to a specific server and not to any other servers. As part of this example, transactions associated with CXL.io protocol, which is a PCIe-based non-coherent I/O protocol, may be used to configure the memory devices and the links between the CPUs and the memory modules included in the far memory provisioned via chassis 200. The CXL.io protocol may also be used by the CPUs associated with the various servers in device discovery, enumeration, error reporting, and management. Alternatively, any other I/O protocol that supports such configuration transactions may also be used. The memory access to the memory modules may be handled via the transactions associated with CXL.mem protocol, which is a memory access protocol that supports memory transactions. As an example, load instructions and store instructions associated with any of the CPUs may be handled via CXL.mem protocol. Although FIG. 2 shows memory chassis 200 as having a certain number of components, including far memory controllers and memory modules, arranged in a certain manner, memory chassis 200 may include additional or fewer components, arranged differently.

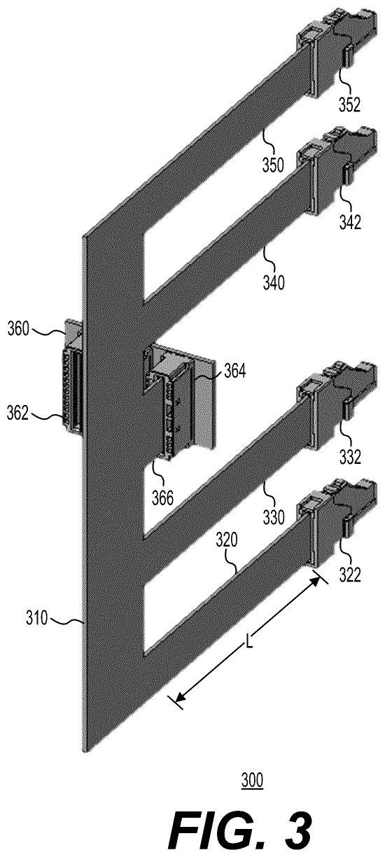

FIG. 3 shows an example multi-finger planar circuit board 300 for use with system 100 of FIG. 1. In this example, multi-finger planar circuit board 300 corresponds to any of multi-finger planar circuit boards 162, 164, 166, 168, 182, 184, 186, and 188. Multi-finger planar circuit board 300 may include fingers 320, 330, 340, and 350 extending from a portion 310 of multi-finger planar circuit board 300. Portion 310 may act as that portion of multi-finger planar circuit board 300 that interconnects the fingers and acts as the body portion from which respective fingers may extend. Each finger may have a length (L) that is selected based on the length of a chassis in the X direction shown in FIG. 1. Middle finger 366, extending from portion 310 of multi-finger planar circuit board 300 may be shorter in length. Each finger may have at least one connector for allowing a coupling with connectors associated with each chassis. Thus, in this example, finger 320 may have an associated connector 322, finger 330 may have an associated connector 332, finger 340 may have an associated connector 342, and finger 350 may have an associated connector 352. Connectors 322, 332, 342, and 352 may connect with other respective connectors or wires in order to allow the exchange of signals from electronic devices associated with a chassis to electronic devices associated with electronic devices associated with another chassis.

With continued reference to FIG. 3, middle finger 366, extending from portion 310 of multi-finger planar circuit board 300, may be coupled to a circuit board 360 with additional connectors (e.g., connectors 362 and 364) mounted on it. In this example, multi-finger planar circuit board 300 may be a printed circuit board with signal lines formed as part of the circuit board using circuit board manufacturing techniques. Multi-finger planar circuit board 300 may include a fiberglass sheet sandwiched between copper sheets (or similar metal or alloy sheets). Wires may be formed by etching wire patterns and removing copper (or a similar metal) where the wires are not desirable. Holes may be formed to create connections for leads or other wires. Substrates other than fiberglass sheets may also be used. Although FIG. 3 shows multi-finger planar circuit board 300 as having a certain number of fingers arranged in a certain manner, multi-finger planar circuit board 300 may include additional or fewer fingers that are arranged differently.

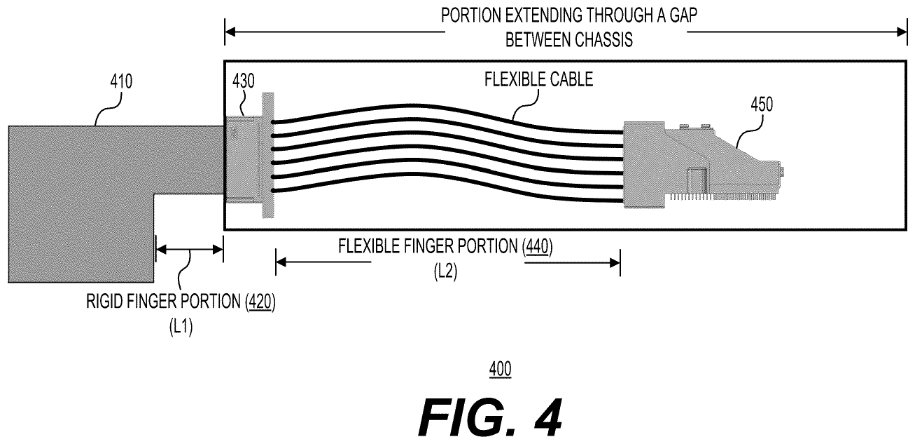

FIG. 4 shows a modified finger 400 for use with multi-finger planar circuit board 300 of FIG. 3. Modified finger 400 may be used to address breakage or other stress-induced damage caused to the fingers that may extend lengthwise inside a gap between the chassis. During service and installation, these fingers may experience mechanical stress causing fractures or other failures, including wiring failures. Modified finger 400 may include a rigid finger portion 420 extending from portion 410 (similar to portion 310 of multi-finger planar circuit board 300). Modified finger 400 may further include a flexible finger portion 440 coupled to rigid finger portion 420 via a floating connector 430. Flexible finger portion 440 may be implemented using a flexible cable. Rigid finger portion 420 may have a length L1 and flexible finger portion may have a length of L2. These lengths may be selected based on the size of the chassis and other considerations. Flexible finger portion 440 may have an associated connector 450 similar to the connectors described earlier. Although FIG. 4 shows modified finger 400 as having a certain structure, modified finger 400 may have a different structure and may include additional or fewer connectors.

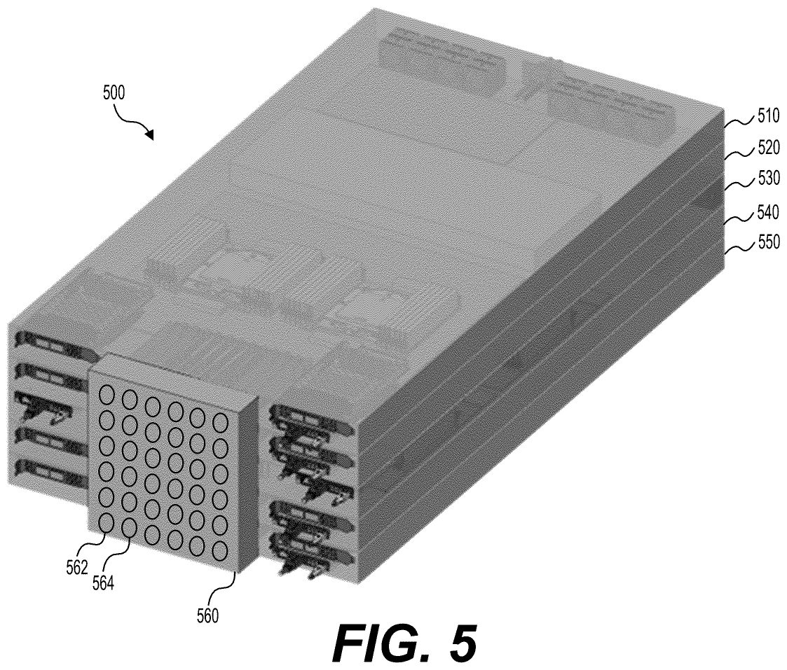

FIG. 5 shows a block diagram of a system 500 (similar to system 100 of FIG. 1) with a cover 560 configured to both reduce electromagnetic interference and deter tampering with the planar circuit board. System 500 may include multiple chassis (e.g., chassis 510, 520, 530, 540, and 550) as described with respect to FIG. 1. Additional details of system 500 are identical to system 100 of FIG. 1. Cover 560 is configured to cover the multi-finger planar circuit boards (e.g., multi-finger planar circuit boards 162, 164, 166, 168, 182, 184, 186, and 188 of FIG. 1). Cover 560 may be perforated to allow for the passage of air. In this example, cover 560 may include several perforations similar to perforations 562 and 564. Cover 560 may also be configured such that any tampering or unauthorized removal of the cover results in an alarm or another type of notification. Various types of tamper detection devices (e.g., switches and associated circuits/software) may be used to configure cover 560 in a manner that such tamper detection can be performed. Although FIG. 5 shows a certain cover 560 arranged in a certain manner, system 500 may include multiple covers that may be arranged differently.

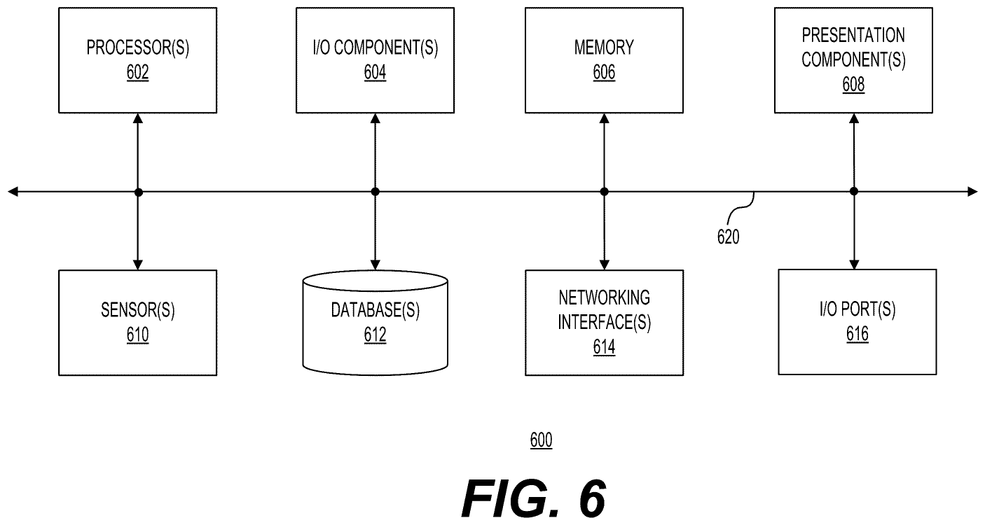

FIG. 6 shows a block diagram of an example computing system 600 implemented using the system of FIG. 1. Computing system 600 may include processor(s) 602, I/O component(s) 604, memory 606, presentation component(s) 608, sensors 610, database(s) 612, networking interfaces 614, and I/O port(s) 616, which may be interconnected via bus 620. Processor(s) 602 may execute instructions stored in memory 606. I/O component(s) 604 may include components such as a keyboard, a mouse, a voice recognition processor, or touch screens. Memory 606 may be any combination of non-volatile storage or volatile storage (e.g., flash memory, DRAM, SRAM, or other types of memories). Presentation component(s) 608 may include displays, holographic devices, or other presentation devices. Displays may be any type of display, such as LCD, LED, or other types of display. Sensor(s) 610 may include telemetry or other types of sensors configured to detect, and/or receive, information (e.g., collected data). Sensor(s) 610 may include telemetry or other types of sensors configured to detect, and/or receive, information (e.g., memory usage by various compute entities being executed by various compute nodes in a data center). Sensor(s) 610 may include sensors configured to sense conditions associated with CPUs, memory or other storage components, FPGAs, motherboards, baseboard management controllers, or the like. Sensor(s) 610 may also include sensors configured to sense conditions associated with racks, chassis, fans, power supply units (PSUs), or the like. Sensor(s) 610 may also include sensors configured to sense conditions associated with Network Interface Controllers (NICs), Top-of-Rack (TOR) switches, Middle-of-Rack (MOR) switches, routers, power distribution units (PDUs), rack level uninterrupted power supply (UPS) systems, or the like.

Still referring to FIG. 6, database(s) 612 may be used to store any of the data collected or logged and as needed for the performance of methods described herein. Database(s) 612 may be implemented as a collection of distributed databases or as a single database. Network interface(s) 614 may include communication interfaces, such as Ethernet, cellular radio, Bluetooth radio, UWB radio, or other types of wireless or wired communication interfaces. I/O port(s) 616 may include Ethernet ports, Fiber-optic ports, wireless ports, or other communication or diagnostic ports. Although FIG. 6 shows computing system 600 as including a certain number of components arranged and coupled in a certain way, it may include fewer or additional components arranged and coupled differently. In addition, the functionality associated with computing system 600 may be distributed, as needed.

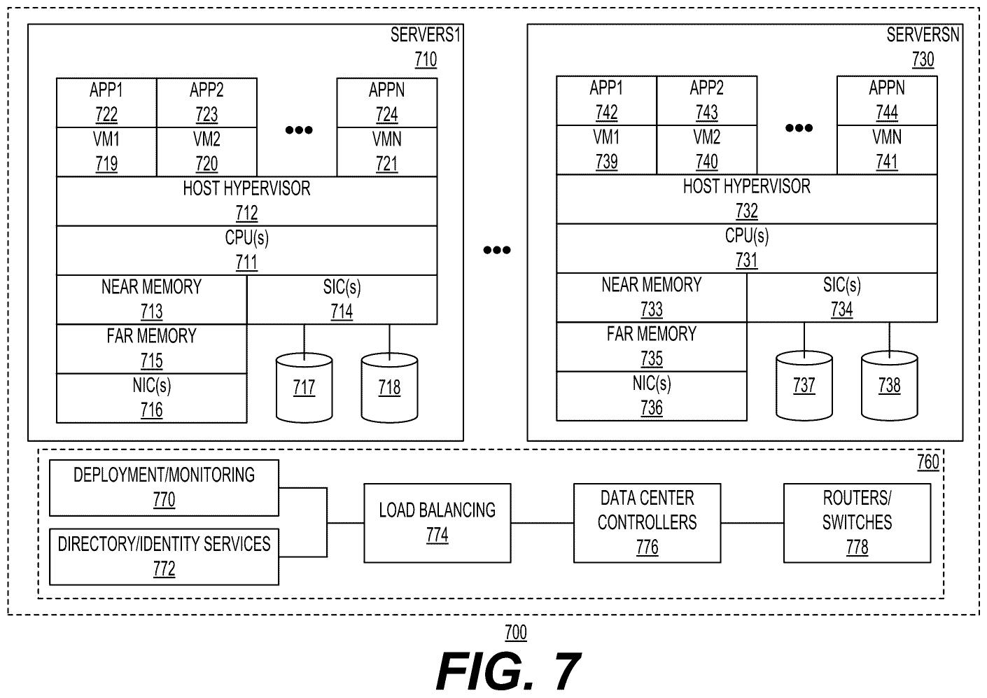

FIG. 7 shows a block diagram of a data center 700 for housing a system including multi-finger planar circuit boards for interconnecting multiple chassis in accordance with one example. As an example, data center 700 may include several clusters of racks including platform hardware, such as compute resources, storage resources, networking resources, or other types of resources. Compute resources may be offered via compute nodes provisioned via servers that may be connected to switches to form a network. The network may enable connections between each possible combination of switches. Data center 700 may include servers1 710 and serversN 730. Data center 700 may further include data center related functionality 760, including deployment/monitoring 770, directory/identity services 772, load balancing 774, data center controllers 776 (e.g., software defined networking (SDN) controllers and other controllers), and routers/switches 778. Servers1 710 may include CPU(s) 711, host hypervisor 712, near memory 713, storage interface controller(s) (SIC(s)) 714, far memory 715, network interface controller(s) (NIC(s)) 716, and storage disks 717 and 718. As explained earlier, far memory 715 may be implemented as a memory modules associated with a memory chassis. ServersN 730 may include CPU(s) 731, host hypervisor 732, near memory 733, storage interface controller(s) (SIC(s)) 734, far memory 735, network interface controller(s) (NIC(s)) 736, and storage disks 737 and 738. As explained earlier, far memory 735 may be implemented as a memory modules associated with a memory chassis. Servers1 710 may be configured to support virtual machines, including VM1 719, VM2 720, and VMN 721. The virtual machines may further be configured to support applications, such as APP1 722, APP2 723, and APPN 724. ServersN 730 may be configured to support virtual machines, including VM1 739, VM2 740, and VMN 741. The virtual machines may further be configured to support applications, such as APP1 742, APP2 743, and APPN 744.

With continued reference to FIG. 7, in one example, data center 700 may be enabled for multiple tenants using the Virtual eXtensible Local Area Network (VXLAN) framework. Each virtual machine (VM) may be allowed to communicate with VMs in the same VXLAN segment. Each VXLAN segment may be identified by a VXLAN Network Identifier (VNI). Although FIG. 7 shows data center 700 as including a certain number of components arranged and coupled in a certain way, it may include fewer or additional components arranged and coupled differently. In addition, the functionality associated with data center 700 may be distributed or combined, as needed.

In conclusion, the present disclosure relates to a system comprising a first chassis including a first set of electronic devices corresponding to a first server, where the first chassis is arranged in a first plane. The system may further comprise a second chassis including a second set of electronic devices corresponding to a second server, where the second chassis is arranged in a second plane on top of the first plane and parallel to the first plane. The system may further comprise a third chassis including a third set of electronic devices configured to provide a shared resource shareable by the first set of electronic devices and the second set of electronic devices, where the third chassis is arranged in a third plane between the first plane and the second plane.

The system may further comprise a planar circuit board including a plurality of fingers extending from a portion of the planar circuit board. The planar circuit board may be arranged in a fourth plane, orthogonal to each of the first plane, the second plane, and the third plane such that a first finger of the plurality of fingers extends through a first gap between the first chassis and the third chassis, where the first finger is configured to provide a first physical path for an exchange of signals between the first set of electronic devices and the third set of electronic devices, where a second finger of the plurality of fingers extends through a second gap between the second chassis and the third chassis, and where the second finger is configured to provide a second physical path for an exchange of signals between the second set of electronic devices and the third set of electronic devices.

The system may further comprise a cooling system configured to provide an airflow, where the planar circuit board is planar with respect to a principal direction of the airflow. The first finger may comprise a first rigid portion and a first flexible portion, and the second finger may comprise a second rigid portion and a second flexible portion.

The shared resource may comprise a shared memory resource, and at least one of the first set of electronic devices may comprise a first central processing unit (CPU) with access to the shared memory resource, and at least one of the second set of electronic devices may comprise a second CPU with access to the shared memory resource. Alternatively, or additionally, the shared resource may comprise a shared networking resource.

A first subset of the first set of electronic devices may comprise a near memory, and the shared resource may comprise a far memory. At least one of the first set of electronic devices may comprise a first central processing unit (CPU) with access to both the near memory and the far memory. Any data residing in the far memory may be swappable into the near memory from the far memory such that the CPU can access the data even when the third chassis including the third set of electronic devices configured to provide the shared resource is unavailable. The planar circuit board may be covered by a cover configured to both reduce electromagnetic interference and deter tampering with the planar circuit board.

In addition, the present disclosure relates to a system comprising a first chassis including a first set of electronic devices corresponding to a first server, where the first chassis is arranged in a first plane. The system may further comprise a second chassis including a second set of electronic devices corresponding to a second server, where the second chassis is arranged in a second plane on top of the first plane and parallel to the first plane. The system may further comprise a third chassis including a third set of electronic devices configured to provide a shared resource shareable by the first set of electronic devices and the second set of electronic devices, where the third chassis is arranged in a third plane between the first plane and the second plane.

The system may further comprise a planar circuit board including a plurality of fingers extending from a portion of the planar circuit board. The planar circuit board may be arranged in a fourth plane, orthogonal to each of the first plane, the second plane, and the third plane such that a first finger of the plurality of fingers extends through a first gap between the first chassis and the third chassis, where the first finger is configured to provide a first physical path for an exchange of signals between the first set of electronic devices and the third set of electronic devices, where a second finger of the plurality of fingers extends through a second gap between the second chassis and the third chassis, and where the second finger is configured to provide a second physical path for an exchange of signals between the second set of electronic devices and the third set of electronic devices, where the first finger comprises a first rigid portion and a first flexible portion, and where the second finger comprises a second rigid portion and a second flexible portion.

The system may further comprise a cooling system configured to provide an airflow, where the planar circuit board is planar with respect to a principal direction of the airflow. The shared resource may comprise a shared memory resource, and at least one of the first set of electronic devices may comprise a first central processing unit (CPU) with access to the shared memory resource, and at least one of the second set of electronic devices may comprise a second CPU with access to the shared memory resource. Alternatively, or additionally, the shared resource may comprise a shared networking resource.

A first subset of the first set of electronic devices may comprise a near memory, and the shared resource may comprise a far memory. At least one of the first set of electronic devices may comprise a first central processing unit (CPU) with access to both the near memory and the far memory. Any data residing in the far memory may be swappable into the near memory from the far memory such that the CPU can access the data even when the third chassis including the third set of electronic devices configured to provide the shared resource is unavailable. The planar circuit board may be covered by a cover configured to both reduce electromagnetic interference and deter tampering with the planar circuit board.

In addition, the present disclosure relates to a system comprising a first chassis including a first set of electronic devices corresponding to a first server, where the first chassis is arranged in a first plane. The system may further comprise a second chassis including a second set of electronic devices corresponding to a second server, where the second chassis is arranged in a second plane on top of the first plane and parallel to the first plane. The system may further comprise a third chassis including a third set of electronic devices configured to provide a shared resource shareable by the first set of electronic devices and the second set of electronic devices, where the third chassis is arranged in a third plane between the first plane and the second plane.

The system may further comprise a planar circuit board including a plurality of fingers extending from a portion of the planar circuit board. The planar circuit board may be arranged in a fourth plane, orthogonal to each of the first plane, the second plane, and the third plane such that a first finger of the plurality of fingers extends through a first gap between the first chassis and the third chassis, where the first finger is configured to provide a first physical path for an exchange of signals between the first set of electronic devices and the third set of electronic devices, where a second finger of the plurality of fingers extends through a second gap between the second chassis and the third chassis, where the second finger is configured to provide a second physical path for an exchange of signals between the second set of electronic devices and the third set of electronic devices, and where neither the first physical path nor the second physical path comprises any signal conditioning components configured to retime or amplify any signals.

The system may further comprise a cooling system configured to provide an airflow, where the planar circuit board is planar with respect to a principal direction of the airflow. The first finger may comprise a first rigid portion and a first flexible portion, and the second finger may comprise a second rigid portion and a second flexible portion.

The shared resource may comprise a shared memory resource, and at least one of the first set of electronic devices may comprise a first central processing unit (CPU) with access to the shared memory resource, and at least one of the second set of electronic devices may comprise a second CPU with access to the shared memory resource. Alternatively, or additionally, the shared resource may comprise a shared networking resource.

A first subset of the first set of electronic devices may comprise a near memory, and the shared resource may comprise a far memory. At least one of the first set of electronic devices may comprise a first central processing unit (CPU) with access to both the near memory and the far memory. Any data residing in the far memory may be swappable into the near memory from the far memory such that the CPU can access the data even when the third chassis including the third set of electronic devices configured to provide the shared resource is unavailable. The planar circuit board may be covered by a cover configured to both reduce electromagnetic interference and deter tampering with the planar circuit board.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), System-on-a-Chip systems (SOCs), Complex Programmable Logic Devices (CPLDs), etc. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality. Merely because a component, which may be an apparatus, a structure, a system, or any other implementation of a functionality, is described herein as being coupled to another component does not mean that the components are necessarily separate components. As an example, a component A described as being coupled to another component B may be a sub-component of the component B, the component B may be a sub-component of the component A, or components A and B may be a combined sub-component of another component C.

The functionality associated with some examples described in this disclosure can also include instructions stored in a non-transitory media. The term “non-transitory media” as used herein refers to any media storing data and/or instructions that cause a machine to operate in a specific manner. Exemplary non-transitory media include non-volatile media and/or volatile media. Non-volatile media include, for example, a hard disk, a solid-state drive, a magnetic disk or tape, an optical disk or tape, a flash memory, an EPROM, NVRAM, PRAM, or other such media, or networked versions of such media. Volatile media include, for example, dynamic memory such as DRAM, SRAM, a cache, or other such media. Non-transitory media is distinct from, but can be used in conjunction with transmission media. Transmission media is used for transferring data and/or instruction to or from a machine. Exemplary transmission media include coaxial cables, fiber-optic cables, copper wires, and wireless media, such as radio waves.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A system comprising:
a first chassis including a first set of electronic devices corresponding to a first server, wherein the first chassis is arranged in a first plane;
a second chassis including a second set of electronic devices corresponding to a second server, wherein the second chassis is arranged in a second plane on top of the first plane and parallel to the first plane;
a third chassis including a third set of electronic devices configured to provide a shared resource shareable by the first set of electronic devices and the second set of electronic devices, wherein the third chassis is arranged in a third plane between the first plane and the second plane; and
a planar circuit board including a plurality of fingers extending from a portion of the planar circuit board, wherein the planar circuit board is arranged in a fourth plane, orthogonal to each of the first plane, the second plane, and the third plane such that a first finger of the plurality of fingers extends through a first gap between the first chassis and the third chassis, wherein the first finger is configured to provide a first physical path for an exchange of signals between the first set of electronic devices and the third set of electronic devices, wherein a second finger of the plurality of fingers extends through a second gap between the second chassis and the third chassis, and wherein the second finger is configured to provide a second physical path for an exchange of signals between the second set of electronic devices and the third set of electronic devices.

2. The system of claim 1, wherein the system further comprises a cooling system configured to provide an airflow, and wherein the planar circuit board is planar with respect to a principal direction of the airflow.

3. The system of claim 2, wherein the first finger comprises a first rigid portion and a first flexible portion, and wherein the second finger comprises a second rigid portion and a second flexible portion.

4. The system of claim 1, wherein the shared resource comprises a shared memory resource, and wherein at least one of the first set of electronic devices comprises a first central processing unit (CPU) with access to the shared memory resource, and wherein at least one of the second set of electronic devices comprises a second CPU with access to the shared memory resource.

5. The system of claim 1, wherein the shared resource comprises a shared networking resource.

6. The system of claim 1, wherein a first subset of the first set of electronic devices comprises a near memory, wherein the shared resource comprises a far memory, wherein at least one of the first set of electronic devices comprises a first central processing unit (CPU) with access to both the near memory and the far memory, and wherein any data residing in the far memory is swappable into the near memory from the far memory such that the CPU can access the data even when the third chassis including the third set of electronic devices configured to provide the shared resource is unavailable.

7. The system of claim 1, wherein the planar circuit board is covered by a cover configured to both reduce electromagnetic interference and deter tampering with the planar circuit board.

8. A system comprising:
a first chassis including a first set of electronic devices corresponding to a first server, wherein the first chassis is arranged in a first plane;
a second chassis including a second set of electronic devices corresponding to a second server, wherein the second chassis is arranged in a second plane on top of the first plane and parallel to the first plane;
a third chassis including a third set of electronic devices configured to provide a shared resource shareable by the first set of electronic devices and the second set of electronic devices, wherein the third chassis is arranged in a third plane between the first plane and the second plane; and
a planar circuit board including a plurality of fingers extending from a portion of the planar circuit board, wherein the planar circuit board is arranged in a fourth plane, orthogonal to each of the first plane, the second plane, and the third plane such that a first finger of the plurality of fingers extends through a first gap between the first chassis and the third chassis, wherein the first finger is configured to provide a first physical path for an exchange of signals between the first set of electronic devices and the third set of electronic devices, wherein a second finger of the plurality of fingers extends through a second gap between the second chassis and the third chassis, and wherein the second finger is configured to provide a second physical path for an exchange of signals between the second set of electronic devices and the third set of electronic devices, wherein the first finger comprises a first rigid portion and a first flexible portion, and wherein the second finger comprises a second rigid portion and a second flexible portion.

9. The system of claim 8, wherein the system further comprises a cooling system configured to provide an airflow, and wherein the planar circuit board is planar with respect to a principal direction of the airflow.

10. The system of claim 8, wherein the shared resource comprises a shared memory resource, and wherein at least one of the first set of electronic devices comprises a first central processing unit (CPU) with access to the shared memory resource, and wherein at least one of the second set of electronic devices comprises a second CPU with access to the shared memory resource.

11. The system of claim 8, wherein the shared resource comprises a shared networking resource.

12. The system of claim 8, wherein a first subset of the first set of electronic devices comprises a near memory, wherein the shared resource comprises a far memory, wherein at least one of the first set of electronic devices comprises a first central processing unit (CPU) with access to both the near memory and the far memory, and wherein any data residing in the far memory is swappable into the near memory from the far memory such that the CPU can access the data even when the third chassis including the third set of electronic devices configured to provide the shared resource is unavailable.

13. The system of claim 8, wherein the planar circuit board is covered by a cover configured to both reduce electromagnetic interference and deter tampering with the planar circuit board.

14. A system comprising:
a first chassis including a first set of electronic devices corresponding to a first server, wherein the first chassis is arranged in a first plane;
a second chassis including a second set of electronic devices corresponding to a second server, wherein the second chassis is arranged in a second plane on top of the first plane and parallel to the first plane;
a third chassis including a third set of electronic devices configured to provide a shared resource shareable by the first set of electronic devices and the second set of electronic devices, wherein the third chassis is arranged in a third plane between the first plane and the second plane; and
a planar circuit board including a plurality of fingers extending from a portion of the planar circuit board, wherein the planar circuit board is arranged in a fourth plane, orthogonal to each of the first plane, the second plane, and the third plane such that a first finger of the plurality of fingers extends through a first gap between the first chassis and the third chassis, wherein the first finger is configured to provide a first physical path for an exchange of signals between the first set of electronic devices and the third set of electronic devices, wherein a second finger of the plurality of fingers extends through a second gap between the second chassis and the third chassis, wherein the second finger is configured to provide a second physical path for an exchange of signals between the second set of electronic devices and the third set of electronic devices, and wherein neither the first physical path nor the second physical path comprises any signal conditioning components configured to retime or amplify any signals.

15. The system of claim 14, wherein the system further comprises a cooling system configured to provide an airflow, and wherein the planar circuit board is planar with respect to a principal direction of the airflow.

16. The system of claim 14, wherein the first finger comprises a first rigid portion and a first flexible portion, and wherein the second finger comprises a second rigid portion and a second flexible portion.

17. The system of claim 14, wherein the shared resource comprises a shared memory resource, and wherein at least one of the first set of electronic devices comprises a first central processing unit (CPU) with access to the shared memory resource, and wherein at least one of the second set of electronic devices comprises a second CPU with access to the shared memory resource.

18. The system of claim 14, wherein the shared resource comprises a shared networking resource.

19. The system of claim 14, wherein a first subset of the first set of electronic devices comprises a near memory, wherein the shared resource comprises a far memory, wherein at least one of the first set of electronic devices comprises a first central processing unit (CPU) with access to both the near memory and the far memory, and wherein any data residing in the far memory is swappable into the near memory from the far memory such that the CPU can access the data even when the third chassis including the third set of electronic devices configured to provide the shared resource is unavailable.

20. The system of claim 14, wherein the planar circuit board is covered by a cover configured to both reduce electromagnetic interference and deter tampering with the planar circuit board.
